(19) United States
(12) Patent Application Publication
(10) Pub. No.: US 2013/0116956 A1
(43) Pub. Date: May 9, 2013

(54) CAPACITANCE MEASUREMENT CIRCUIT

(71) Applicants: QI-YAN LUO, Shenzhen City (CN); PENG CHEN, Shenzhen City (CN); SONG-LIN TONG, Shenzhen City (CN)

(72) Inventors: QI-YAN LUO, Shenzhen City (CN); PENG CHEN, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/326,232

(22) Filed: Dec. 14, 2011

(30) Foreign Application Priority Data
Nov. 8, 2011 (CN) 201110349610.9

(51) Int. Cl. G06F 19/00; G01R 27/26

(52) U.S. Cl. 702/65

(57) ABSTRACT

A capacitance measurement circuit includes a charge module to charge a capacitor, a discharge module to hold the capacitor discharge at a constant current, and a control module. The control module includes a timer, a detecting sub-module, a trigger sub-module, and a computing sub-module. The detecting sub-module detects whether the capacitance is fully charged and detects voltages V and discharge current I when the capacitor discharges. The trigger sub-module triggers the charge module to stop charging the capacitor and triggers the timer starts to time a preset discharge time once the capacitor is fully charged. The computing sub-module computes any output voltage differences during the discharge time, and further computes the capacitance value of the capacitor.

### BACKGROUND

1. Technical Field

The present disclosure relates to a capacitance measurement circuit for measuring the capacitance value of a super capacitor.

2. Description of Related Art

A super capacitor is an electrochemical capacitor with higher energy density and capable of higher rates of charge and discharge. Super capacitors are widely used in electronic devices. Although the packaging of a capacitor may indicate the capacitance values of the super capacitor, the capacitance of the super capacitor may changed after a number of charges and discharges, thus the real capacitance values of the super capacitor is no longer the same as those on the packaging.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a block diagram of a capacitance measurement circuit in accordance with an exemplary embodiment.

FIG. 2 is a circuit diagram of a charge module circuit of the capacitance measurement circuit of FIG. 1 for charging a super capacitor in accordance with an exemplary embodiment.

FIG. 3 is a circuit diagram of a discharge module circuit of the capacitance measurement circuit of FIG. 1 for discharging the super capacitor in accordance with an exemplary embodiment.

### DETAILED DESCRIPTION

Embodiments of the present disclosure will be described with reference to the accompanying drawings.

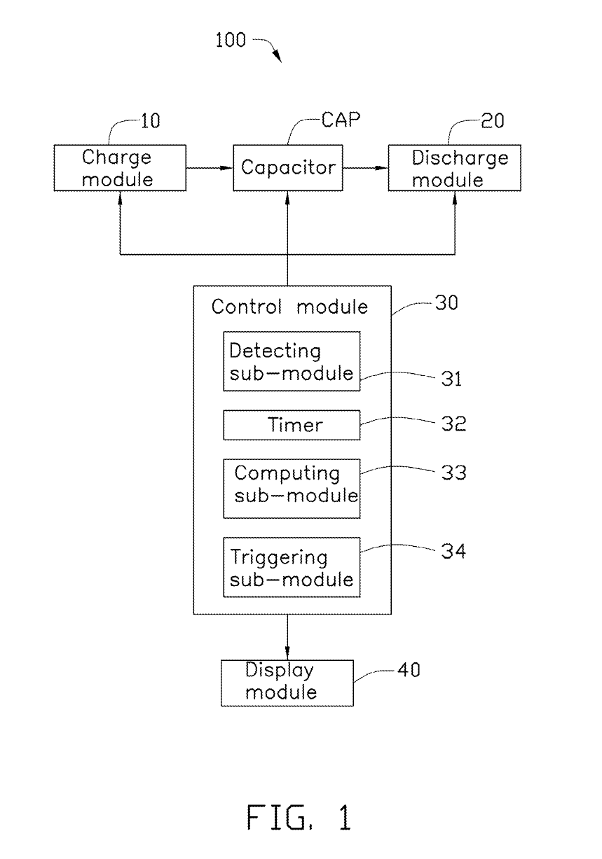

Referring to FIG. 1, a capacitance measurement circuit 100 is used to measure the capacitance C of a capacitor CAP. In this embodiment, the capacitor CAP is a super capacitor. The circuit 100 includes a charge module 10, a discharge module 20, a control module 30, and a display module 40. The control module 30 includes a detecting sub-module 31, a timer 32, a computing sub-module 33, and a triggering sub-module 34. The charge module 10 is configured to charge the capacitor CAP. The detecting sub-module 31 is configured to detect whether the capacitor CAP is fully charged. When the detecting sub-module 31 determines that the capacitor CAP is fully charged, the triggering sub-module 34 triggers the charge module 10 to stop charging the capacitor CAP and triggers the timer 32 start to time the discharge time ΔT during which the capacitor CAP discharges. The triggering sub-module 34 further triggers the discharge module 20 to discharge the capacitor CAP at a constant current I when the detecting sub-module 31 determines that the capacitor CAP is fully charged. The detecting sub-module 31 further detects the voltage V of the capacitor CAP and the constant discharge current I during the discharging time of the capacitor CAP. In this embodiment, the discharge time ΔT is preset. The computing sub-module 33 computes any changes in the voltage being output by the capacitor CAP during the discharge (voltage difference ΔV) according to the voltages detected by the detecting sub-module 31 during the discharge time ΔT. The computing sub-module 33 further computes the capacitance value C of the capacitor CAP according to a formula C*ΔV=I*ΔT.

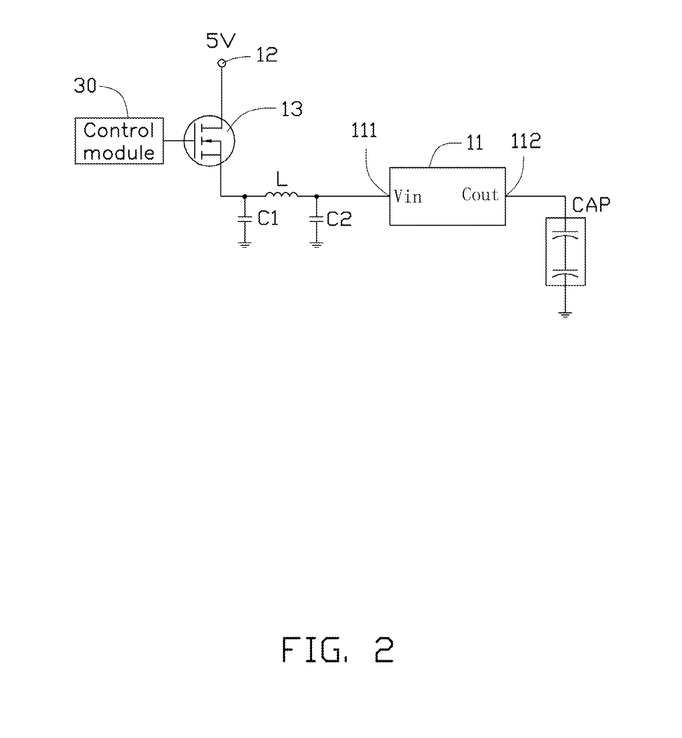

Referring to FIG. 2, the charge module 10 includes a charge control chip 11, a power interface 12, and a switch circuit 13. The charge control chip 11 includes an input pin 111 and an output pin 112. The switch circuit 13 is connected between the power interface 12 and the input pin 111. The output pin 112 is connected to the anode of the capacitor CAP. The triggering sub-module 34 triggers the switch circuit 13 to connect the power interface 12 and the input pin 11 when the detecting sub-module 31 determines that the capacitor CAP remains to be fully charged, thus the power interface 12 provides DC power to the input pin 111. The triggering sub-module 34 triggers the switch circuit 13 to disconnect the power interface 12 and the input pin 11 when the detecting sub-module 31 determines that the capacitor CAP is fully charged, and the power interface 12 stops providing DC power to the input pin 111. The charge control chip 11 charges the capacitor CAP through the output pin 112 when the power interface 12 is providing power to the input pin 111.

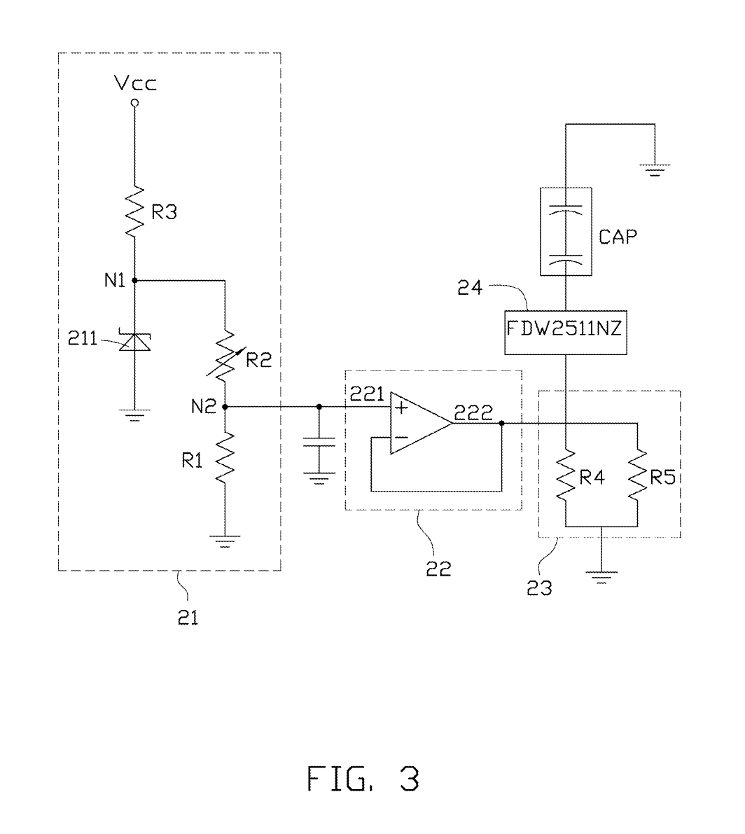

Referring to FIG. 3, the discharge module 20 includes a voltage regulator circuit 21, a voltage follower 22, a resistance module 23, and an adaptive impedance adjustment circuit 24. The voltage regulator circuit 21 provides a constant voltage. In this embodiment, the voltage regulator circuit 21 includes a power supply Vcc, a Zener diode 211, a first resistor R1, a second resistor R2, and a third resistor R3. The Zener diode 211 and the third resistor R3 are serially connected between the power supply Vcc and ground. The first resistor R1 and the second resistor R2 are serially connected between a connection node N1 (between the Zener diode 211 and the third resistance R3), and ground. A connection node N2 between the first resistor R1 and the second resistor R2 forms the output terminal of the voltage regulator circuit 21. The Zener diode 211 automatically maintains a constant voltage to the first node N1, and the second node N2 also outputs a constant but different voltage (specific constant voltage value)because the first resistor R1 and the second resistor R2 split the constant voltage outputted to the first node N1. The specific constant voltage value at the second node N2 is determined by the ratio of the resistance value of the first resistor R1 dividing that of the second resistor R2. The specific constant voltage value can be adjusted by adjusting the ratio of the relative resistance values of the first and second resistors R1 and R2. In this embodiment, the resistance value of one or both of the first resistor R1 and the second resistor R2 is adjustable. In alternative embodiments, the Zener diode 211 may be replaced by a three-terminal adjustable shunt regulator TL431.

An input terminal 221 of the voltage follower 22 is connected to the second connection node N2. In this embodiment, the voltage follower 22 is an operational amplifier, the non-inverting input of the operational amplifier is the input terminal 221, the inverting input of the operational amplifier is connected to the output of the operational amplifier, and the output of the operational amplifier is the output terminal 222 of the voltage follower 22. The voltage value at the input terminal 221 is equal to that of the output terminal 222.

The resistance module 23 has a constant resistance value and is connected to the output terminal 222. Thus the current in the resistance module 23 is constant because of the constant output voltage value at the output terminal 222. In this embodiment, the resistance module 23 includes a forth resistor R4 and a fifth resistor R5 connected in parallel between the output terminal 222 and ground. In alternative embodiments, the output of the voltage regulator circuit 21 is directly connected to the resistance module 23.

The adaptive impedance adjustment circuit 24 is connected between the resistance module 23 and the anode of the capacitor CAP. During the discharging of the capacitor CAP, the impedance of the adaptive impedance adjustment circuit 24 can be automatically adjusted according to any change of the voltage of the capacitor CAP, to keep the discharge current I equal to the constant current in the resistance module 23 at all times. In this embodiment, the adaptive impedance adjustment circuit 24 is a chip FDW2511NZ.

After the capacitance C of the capacitor CAP is computed by the computing sub-module 33, the display module 40 may display the capacitance value C, the discharge current I, the voltage value V of the capacitor CAP, and the discharge time ΔT to the user as required.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A capacitance measurement circuit configured to measure the capacitance value of a capacitor, comprising:
a charge module to charge the capacitor;
a discharge module to control the capacitor discharge in a constant discharge current I;
a control module comprising:
a timer;
a detecting sub-module to detect whether the capacitor is fully charged, and detect the voltage value V and the discharge current I of the capacitor;
a triggering sub-module to trigger the charge module to stop charging the capacitor when the detecting sub-module determines that the capacitor is fully charged, and simultaneously, trigger the timer to start to time for a preset discharge time ΔT during discharging time of the capacitor;
a computing sub-module to compute a voltage difference AV of the capacitor during a discharge time ΔT the capacitor discharges according to the voltage values the detecting sub-module detected, and compute the capacitance value C of the capacitor according to a formula C*ΔV=I*ΔT.

2. The capacitance measurement circuit as described in claim 1, wherein the charge module comprises a charge control chip, a power interface, and a switch circuit, the charge control chip comprises an input pin and an output pin, the switch circuit is connected between the power interface and the input pin, the output pin is connected to the anode of the capacitor, the triggering sub-module triggers the switch circuit to connect the power interface and the input pin when the detecting sub-module determines the capacitor is not fully charged, the power interface provides DC power to the input pin, the triggering sub-module triggers the switch circuit to disconnect the power interface and the input pin when the detecting sub-module determines the capacitor is fully charged, thus the power interface stop providing DC power to the input pin.

3. The capacitance measurement circuit as described in claim 1, wherein the discharge module comprises a voltage regulator circuit, a resistance module, and an adaptive impedance adjustment circuit, the voltage regulator circuit provides a constant voltage value, the resistance module has a constant resistance value and is connected between the output of the voltage regulator circuit and ground; the adaptive impedance adjustment circuit is connected between the resistance module and the anode of the capacitor, during the capacitor discharge, the impedance of the adaptive impedance adjustment circuit can be automatically adjusted corresponding to the change of the voltage value of the capacitor to keep the discharge current I always equal to the constant current in the resistance module.

4. The capacitance measurement circuit as described in claim 3, wherein the discharge module further comprises a voltage follower, the voltage follower comprises an input terminal and an output terminal, the input terminal is connected to the output of the voltage regulator circuit and the output terminal is connected to the resistance module.

5. The capacitance measurement circuit as described in claim 4, wherein the voltage regulator circuit comprises a power supply, a Zener diode, a first resistor, a second resistor, and a third resistor, the Zener diode and the third resistor are series connected between the power supply and ground, the first resistor and the second resistor are series connected between a connection node, which is defined between the Zener diode and the third resistor, and ground, and a connection node defined between the first resistor and the second resistor forms the output terminal of the voltage regulator circuit.

6. The capacitance measurement circuit as described in claim 5, wherein the resistance value of one or both of the first resistor and the second resistor is adjustable.

7. The capacitance measurement circuit as described in claim 4, wherein the voltage follower is an operational amplifier, the non-inverting input of the operational amplifier is the input terminal of the voltage follower, the inverting input of the operational amplifier is connected to the output of the operational amplifier, and the output of the operational amplifier is the output terminal of the voltage follower, the voltage value in the input terminal is equal to that of the output terminal.

8. The capacitance measurement circuit as described in claim 3, wherein the Zener diode can be replaced by a three-terminal adjustable shunt regulator.

9. The capacitance measurement circuit as described in claim 3, wherein the adaptive impedance adjustment circuit is a chip FDW2511NZ whose impedance is capable of being adjusted automatically corresponding to the change of the voltage of the capacitor to maintain the discharge current I always equal with the constant current in the resistance module.

10. The capacitance measurement circuit as described in claim 1, further comprising a display module to display the computed capacitance value C, the discharge current I, the voltage value V of the capacitor CAP, and the discharge time ΔT to the user.
